(19) United States
(12) Patent Application Publication
(10) Pub. No.: US 2023/0223908 A1
(43) Pub. Date: Jul. 13, 2023

(54) Single crystal film bulk acoustic resonator, manufacturing method for single crystal film bulk acoustic resonator, and filter

(71) Applicant: Wuhan MEMSonics Technologies Co.,Ltd., Wuhan (CN)

(72) Inventors: Yang ZOU, Wuhan (CN); Yao CAI, Wuhan (CN); Binghui LIN, Wuhan (CN); Tiancheng LUO, Wuhan (CN); Chao GAO, Wuhan (CN); Dawdon CHEAM, Wuhan (CN); Bowoon SOON, Singapore (SG); Chengliang SUN, Wuhan (CN)

(21) Appl. No.: 17/987,891

(22) Filed: Nov. 16, 2022

(30) Foreign Application Priority Data
Jan. 11, 2022 (CN) 202210027314.5

(51) Int. Cl. H03H 3/02; H03H 9/17; H03H 9/13; H03H 9/05; H03H 9/02; H03H 9/56

(52) U.S. Cl. CPC H03H 3/02; H03H 9/172; H03H 9/133; H03H 9/0514; H03H 9/02015; H03H 9/566; H03H 2003/021

(57) ABSTRACT

The present disclosure provides a single crystal film bulk acoustic resonator, a manufacturing method for a single crystal film bulk acoustic resonator, and a filter, and relates to the technical field of filters. The method includes: sequentially forming a buffer layer, a piezoelectric layer, and a first electrode that are stacked on a temporary base substrate; forming a first bonding layer on the first electrode; providing a substrate; etching the substrate to form a plurality of first bumps on a surface of the substrate; forming a second bonding layer covering top surfaces of the plurality of first bumps on the surface of the substrate; and bonding the second bonding layer located at the top surfaces of the plurality of first bumps to the first bonding layer. During bonding, the area of the top surfaces of the first bumps can be controlled by etched grooves, so the area of the second bonding layer located at the top surfaces of the first bumps can be controlled, thereby realizing the control of a bonding area. By controlling the bonding area, the balance between the bonding requirement and the bonding reliability is realized.

### CROSS-REFERENCE TO RELATED APPLICATION

This present disclosure claims the priority to Chinese patent application No. 202210027314.5, entitled “Single crystal film bulk acoustic resonator, manufacturing method for single crystal film bulk acoustic resonator, and filter”, and filed on Jan. 11, 2022 in China, which is hereby incorporated by reference in its entirety.

### TECHNICAL FIELD

The present disclosure relates to the technical field of filters, in particular to a single crystal film bulk acoustic resonator, a manufacturing method for a single crystal film bulk acoustic resonator, and a filter.

### BACKGROUND

A film bulk acoustic resonator generates resonance by using a piezoelectric effect of a piezoelectric crystal. Since the resonance is generated by a mechanical wave, rather than taking an electromagnetic wave as a source, the wavelength of the mechanical wave is much shorter than that of electromagnetic wave. Therefore, the size of the film bulk acoustic resonator is greatly reduced compared with the size of a conventional electromagnetic filter. In one aspect, the crystal orientation growth of the piezoelectric crystal can be well controlled at present, so the loss of the resonator is extremely low, the quality factor is high, which can meet the complex design requirements such as steep transition band, low insertion loss, and the like. Since the film bulk acoustic resonator has the characteristics of small size, high roll-off, low insertion loss, and the like, filters based on this core have been widely used in communication systems.

The existing single crystal film bulk acoustic resonator will adopt a bonding process during manufacturing. However, in the actual bonding process, it is difficult to effectively control the bonding area, which is easy to reduce the bonding reliability.

### SUMMARY

A purpose of the present disclosure is to provide a single crystal film bulk acoustic resonator, a manufacturing method for a single crystal film bulk acoustic resonator, and a filter in view of the abovementioned shortcomings in the related art, which can control the bonding area and improve the bonding reliability.

In order to achieve the abovementioned purpose, the embodiments of the present disclosure adopt the following technical solutions.

In one aspect of the embodiments of the present disclosure, a manufacturing method for a single crystal film bulk acoustic resonator, a manufacturing method for a single crystal film bulk acoustic resonator, and a filter are provided. The method includes that: a temporary base substrate is provided; a buffer layer, a piezoelectric layer, and a first electrode that are stacked on a temporary base substrate are sequentially formed; a first bonding layer is formed on the first electrode; a substrate is provided; the substrate is etched to form a plurality of first bumps on a surface of the substrate; a second bonding layer covering top surfaces of the plurality of first bumps is formed on the surface of the substrate; the second bonding layer located at the top surfaces of the plurality of first bumps is bonded to the first bonding layer; the temporary base substrate is removed; the buffer layer is etched to form a first groove that exposes the piezoelectric layer; and a second electrode that is in contact with the piezoelectric layer is formed through the first groove.

Optionally, after the first bonding layer is formed on the first electrode, the method further includes that: the first bonding layer is patterned to form a plurality of second bumps for bonding with second bonding layer located at the top surfaces of the first bumps.

Optionally, after the temporary base substrate is removed, the method further includes that: the buffer layer and the piezoelectric layer are etched sequentially to form a second groove that exposes the first electrode; and an extraction electrode connected to the first electrode is formed through the second groove.

Optionally, a plurality of first bumps include a first sub-bump and a second sub-bump. A third groove corresponding to a position of the first groove is formed between the first sub-bump and the second sub-bump.

Optionally, both a first bonding layer and a second bonding layer are metal layers.

Optionally, both the first bonding layer and the second bonding layer are metal layers.

Optionally, a sacrificial layer is deposited on the first electrode, and a support layer and the first bonding layer are deposited on the first electrode and the sacrificial layer.

Optionally, a compressed height of the first bonding layer and the second bonding layer after being bonded is not greater than a height of the first bump.

Optionally, the compressed height of the first bonding layer and the second bonding layer after being bonded is equal to the height of the first bump.

Optionally, the bonding pressure applied to the first bonding layer and the second bonding layer is positively related to an area of the top surface of the first bump.

Optionally, a release hole is formed in the substrate, and the sacrificial layer is removed through the release hole to form a cavity.

In another aspect of the embodiments of the present disclosure, a single crystal film bulk acoustic resonator is provided, which includes: a substrate. A surface of the substrate has a plurality of the first bumps. A second bonding layer covering top surfaces of a plurality of first bumps is formed on the surface of the substrate. A first bonding layer is bonded on the second bonding layer. A first electrode, a piezoelectric layer, and a buffer layer that are stacked are sequentially formed on the first bonding layer. A first groove that exposes the piezoelectric layer is formed in the buffer layer. A second electrode that is in contact with the piezoelectric layer is formed on the first groove.

Optionally, both the first bonding layer and the second bonding layer are metal layers.

Optionally, the first bonding layer and the second bonding layer are of same materials. In yet another aspect of the embodiments of the present disclosure, a filter is provided, which includes a plurality of single crystal film bulk acoustic resonators of any one of the above. a plurality of single crystal film bulk acoustic resonators share a same substrate. a plurality of single crystal film bulk acoustic resonators are connected in series and/or in parallel. A first annular sealing structure surrounding the plurality of single crystal film bulk acoustic resonators is formed on the substrate. The first annular sealing structure includes a first sealing ring and a second sealing ring that are stacked on the substrate and are bonded mutually.

Optionally, a second annular sealing structure is also formed on the periphery of the single crystal film bulk acoustic resonators. The second annular sealing structure includes a third sealing ring and a fourth sealing ring that are stacked on the substrate and are bonded mutually.

Optionally, the filter further includes a sealing wall structure. Two adjacent second annular sealing structures are connected through the sealing wall structure.

Optionally, the sealing wall structure includes a fifth sealing ring and a sixth sealing ring that are stacked on the substrate and are bonded mutually.

Optionally, a side wall of the sealing wall structure forms an inclination angle.

Optionally, the angle of the inclination angle is less than 70°.

The present disclosure has the following beneficial effects.

The present disclosure provides a single crystal film bulk acoustic resonator, a manufacturing method for a single crystal film bulk acoustic resonator, and a filter. The method includes: a buffer layer, a piezoelectric layer, and a first electrode that are stacked are sequentially formed on a temporary base substrate; a first bonding layer is formed on the first electrode; a substrate is provided; the substrate is etched to form a plurality of first bumps on a surface of the substrate; a second bonding layer covering top surfaces of the plurality of first bumps is formed on the surface of the substrate; and the second bonding layer located at the top surfaces of the plurality of first bumps are bonded to the first bonding layer. During bonding, the area of the top surfaces of the first bumps can be controlled by etched grooves, so the area of the second bonding layer located at the top surfaces of the first bumps can be controlled, thereby realizing the control of a bonding area. Through the flexible adjustment of the bonding area, a hierarchical structure on the temporary base substrate and a hierarchical structure on the substrate are prevented from being difficult to apply in mass production due to excessive bonding area, high bonding requirement, and high preparation cost on the basis of meeting the requirements of the bonding reliability. In other words, the present disclosure realizes the balance between the bonding requirement and the bonding reliability by controlling the bonding area.

### BRIEF DESCRIPTION OF THE DRAWINGS

To describe the technical solutions in the embodiments of the present disclosure more clearly, the following briefly introduces the drawings required for describing the embodiments of the present disclosure. It should be understood that the following drawings only show some embodiments of the present disclosure, thus should not be considered as limitation to a scope. Those of ordinary skill in the art may still derive other relevant drawings from these drawings without creative efforts.

FIG. 1 is a schematic flowchart of a manufacturing method for a single crystal film bulk acoustic resonator provided by the embodiments of the present disclosure.

FIG. 2 illustrates a first schematic diagram of a preparation state of a single crystal film bulk acoustic resonator provided by the embodiments of the present disclosure.

FIG. 3 illustrates a second schematic diagram of a preparation state of a single crystal film bulk acoustic resonator provided by the embodiments of the present disclosure.

FIG. 4 illustrates a third schematic diagram of a preparation state of a single crystal film bulk acoustic resonator provided by the embodiments of the present disclosure.

FIG. 5 illustrates a fourth schematic diagram of a preparation state of a single crystal film bulk acoustic resonator provided by the embodiments of the present disclosure.

FIG. 6 illustrates a fifth schematic diagram of a preparation state of a single crystal film bulk acoustic resonator provided by the embodiments of the present disclosure.

FIG. 7 illustrates a sixth schematic diagram of a preparation state of a single crystal film bulk acoustic resonator provided by the embodiments of the present disclosure.

FIG. 8 illustrates a seventh schematic diagram of a preparation state of a single crystal film bulk acoustic resonator provided by the embodiments of the present disclosure.

FIG. 9 illustrates an eighth schematic diagram of a preparation state of a single crystal film bulk acoustic resonator provided by the embodiments of the present disclosure.

FIG. 10 illustrates a schematic structural diagram of a single crystal film bulk acoustic resonator provided by the embodiments of the present disclosure.

FIG. 11 illustrates a first schematic structural diagram of a filter provided by the embodiments of the present disclosure.

FIG. 12 illustrates a second schematic structural diagram of a filter provided by the embodiments of the present disclosure.

FIG. 13 illustrates a ninth schematic diagram of a preparation state of a single crystal film bulk acoustic resonator provided by the embodiments of the present disclosure.

FIG. 14 illustrates a tenth schematic diagram of a preparation state of a single crystal film bulk acoustic resonator provided by the embodiments of the present disclosure.

FIG. 15 illustrates an eleventh schematic diagram of a preparation state of a single crystal film bulk acoustic resonator provided by the embodiments of the present disclosure.

FIG. 16 illustrates a twelfth schematic diagram of a preparation state of a single crystal film bulk acoustic resonator provided by the embodiments of the present disclosure.

FIG. 17 illustrates a thirteenth schematic diagram of a preparation state of a single crystal film bulk acoustic resonator provided by the embodiments of the present disclosure.

FIG. 18 illustrates a fourteenth eighth schematic diagram of a preparation state of a single crystal film bulk acoustic resonator provided by the embodiments of the present disclosure.

FIG. 19 illustrates a fifteenth schematic diagram of a preparation state of a single crystal film bulk acoustic resonator provided by the embodiments of the present disclosure.

FIG. 20 illustrates a sixteenth schematic diagram of a preparation state of a single crystal film bulk acoustic resonator provided by the embodiments of the present disclosure.

FIG. 21 illustrates a seventeenth eighth schematic diagram of a preparation state of a single crystal film bulk acoustic resonator provided by the embodiments of the present disclosure.

FIG. 22 illustrates a third schematic structural diagram of a filter provided by the embodiments of the present disclosure.

FIG. 23 illustrates a C-SEM diagram after small-area Au lift-off (b) bonding in conventional mode (a) provided by a related art.

FIG. 24 illustrates a C-SEM diagram after bonding of the present disclosure.

FIG. 25 illustrates a schematic diagram of an inclination angle of a sealing wall structure provided by the embodiments of this present disclosure.

Reference signs: 101—temporary base substrate; 102—buffer layer; 103—piezoelectric layer; 204—first electrode; 305—second bump; 401—substrate; 406—etched groove; 507—second bonding layer; 808—second groove; 809—first groove; 910—second electrode; 911—extraction electrode; 912—third groove; 1002—single crystal film bulk acoustic resonator; 1003—first annular sealing structure; 1103—second annular sealing structure; 1104—sealing wall structure; and 307—first bonding layer.

### DETAILED DESCRIPTION OF THE EMBODIMENTS

The embodiments stated below represent the information necessary for those skilled in the art to practice the embodiments, and show the best mode to practice the embodiments. After reading the following description with reference to the drawings, those skilled in the art will understand the concepts of the present disclosure, and will recognize the application of these concepts not specifically proposed herein. It is to be understood that these concepts and applications fall within the scope of the present disclosure and the attached claims.

It is to be understood that, the terms first, second, etc. may be used for describing various elements in the present disclosure, but these element should not be limited to these terms. These terms are used only for distinguishing one element from another. For example, without departing from the scope of the present disclosure, a first element may be referred to as a second element, and similarly, the second element may also be referred to as the first element. As used herein, the term “and/or” used herein includes any and all combinations of one or more of the associated listed items.

It is to be understood that when an element (such as a layer, an area, or a substrate) is referred to as “being on another element” or “extending to another element”, it may be directly on another element or directly extend to another element, or there may be an element there between. On the contrary, when on element is referred to as “being directly on another element” or “directly extending to another element”, there is no element there between. Similarly, it is to be understood that when an element (such as a layer, an area, or a substrate) is referred to as “being on another element” or “extending on another element”, it may be directly on another element or directly extend on another element, or there may be an element there between. On the contrary, when an element is referred to as “being directly on another element” or “directly extending on another element”, there is no element there between. It is also understood that when an element is described as being “connected” or “coupled” to another element, it may be directly connected or coupled to another element, or there is an element there between. On the contrary, when an element is referred to as being “directly connected” or “directly coupled” to another element, there is no element there between.

Related terms such as “below” or “above” or “upper” or “lower” or “horizontal” or “vertical” can be used herein for describing the relationship between one element, layer, or area and another element, layer, or area, as shown in the drawings. It is to be understood that these terms and those discussed above are intended to cover different orientations of an apparatus other than those depicted in the drawings.

The terms used in the present disclosure are only used for the purpose of illustrating specific implementation modes, and are not intended to limit the present disclosure. As used herein, singular forms “a”, “an”, and “the” are also intended to include plural forms as well, unless the context explicitly otherwise. It is also to be understood that, when used herein, the term “including” indicates the existence of the features, integers, steps, operations, elements, and/or components, but does not exclude the existence or addition of one or more other features, integers, steps, operations, elements, components, and/or groups of the foregoing.

Unless otherwise defined, all terms used herein (including technical terms and scientific terms) have the same meanings as those commonly understood by those of ordinary in the art of the present disclosure. It is also to be understood that the terms used herein shall be interpreted as having the same meaning as they have in the specification and related fields, and shall not be interpreted in an idealized or overly formal sense, unless they have been explicitly defined herein.

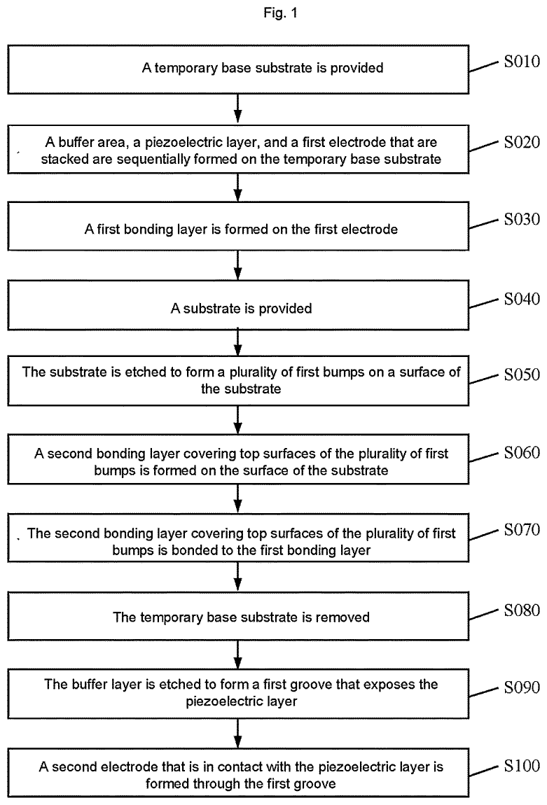

In an aspect of the embodiments of the present disclosure, a manufacturing method for a single crystal film bulk acoustic resonator is provided. As shown in FIG. 1, the method includes the following steps.

At S010: a temporary base substrate is provided.

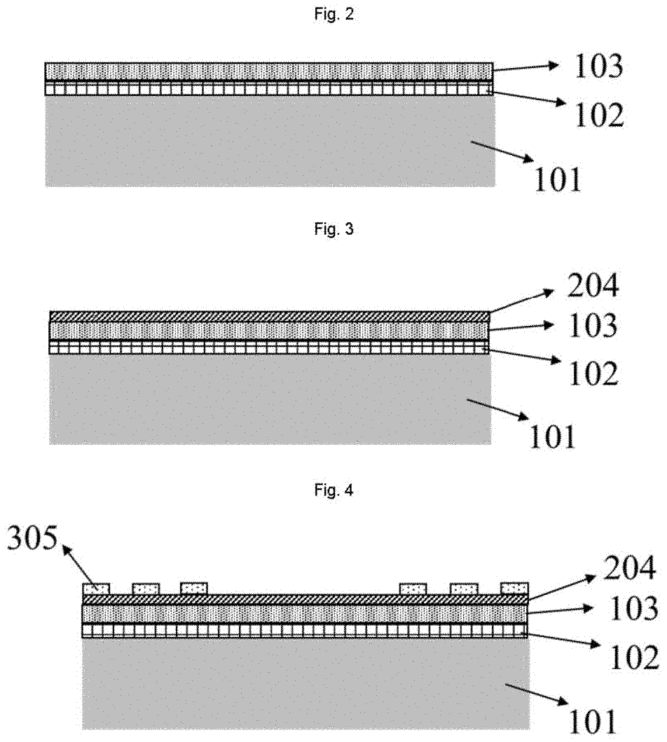

As shown in FIG. 2, a temporary base substrate 101 may be a substrate for carrying semiconductor integrated circuit components, such as a Si base substrate and a sapphire base substrate.

At S020: a buffer layer, a piezoelectric layer, and a first electrode that are stacked are formed on the temporary base substrate sequentially.

As shown in FIG. 2 and FIG. 3, a buffer layer 102, a piezoelectric layer 103, and a first electrode 204 that are stacked are sequentially formed on the temporary base substrate 101. The buffer layer 102 can improve the deposition quality of the piezoelectric layer 103. In some embodiments, the buffer layer 102 may be made of silicon nitride. The piezoelectric layer 103 may be made of one of AlN, ScAlN, ZnO, PZT, LiNbO₃ and LiTaO₃.

At S030: a first bonding layer is formed on the first electrode.

As shown in FIG. 4, after the first electrode 204 is formed, a first bonding layer is continued to be formed on the first electrode 204. At this moment, a hierarchical structure, located on the temporary base substrate 101, of a single crystal film bulk acoustic resonator 1002 is formed.

At S040: a substrate is provided.

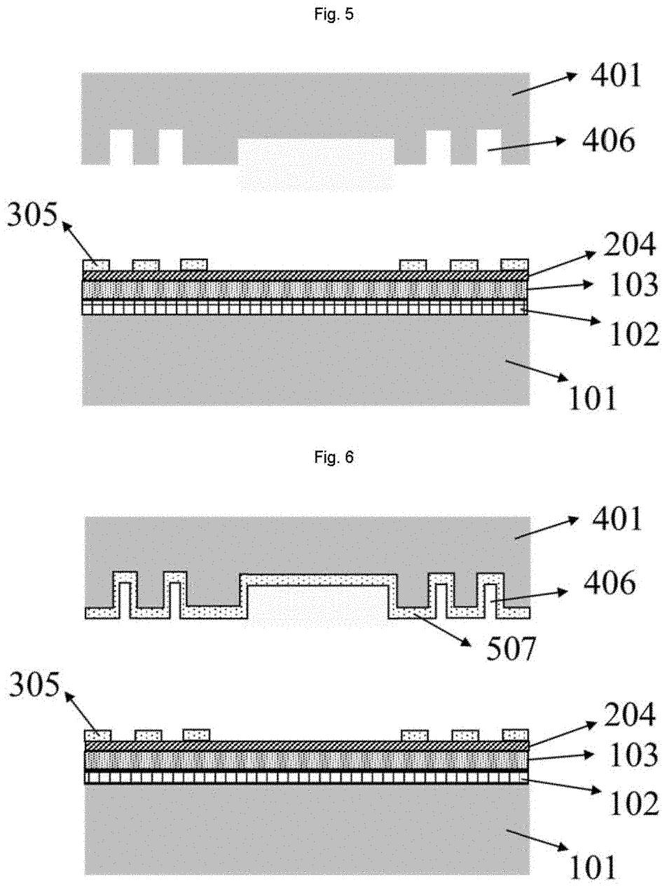

As shown in FIG. 5, a substrate 401 is provided. The substrate 401 may also be a substrate for carrying semiconductor integrated circuit components, such as a Si substrate 401 and a sapphire substrate 401.

At S050: the substrate is etched to form a plurality of first bumps on a surface of the substrate.

As shown in FIG. 5, the surface of the substrate 401 is etched, so as to form a plurality of bumps on one side surface of the substrate 401. Meanwhile, an etched groove 406 sunken into the substrate 401 is synchronously formed between two adjacent first bumps. Thus, the area of the top surface of the first bump is controlled by controlling the size of the etched groove 406. As shown in FIG. 5, six bumps and five etched grooves 406 are formed on the surface of the substrate 401.

It is to be understood that a method for etching the substrate 401 to form the first bumps and the etched grooves 406 may be a method of etching through a mask. For example, a whole layer of dielectric layer may be deposited on the surface of substrate 401, the dielectric layer is coated with a photoresist layer, and the dielectric layer may be patterned by the processes such as exposure, development, and etching. Then, the exposed substrate 401 may be etched to form the etched grooves 406 while correspondingly forming the first bumps at the same time. For another example, the surface of the substrate 401 may be directly coated with the photoresist layer, and the photoresist layer may be patterned through the processes such as exposure and development. Then, the exposed substrate 401 may be etched to form the etched groove 406 while correspondingly forming the first bumps at the same time.

At S060: a second bonding layer covering top surfaces of the plurality of first bumps is formed on the surface of the substrate.

As shown in FIG. 6, a second bonding layer 507 is deposited on the surface of the etched substrate 401. The second bonding layer 507 at least covers the top surface of each first bump. At this moment, a hierarchical structure, located on the substrate 401, of the single crystal film bulk acoustic resonator 1002 is formed. For example, as shown in FIG. 6, a whole layer of second bonding layer 507 is deposited on the surface of the etched substrate 401, that is, the second bonding layer 507 covers the top surfaces and the side surfaces of the first bumps and the bottom surfaces of the etched grooves 406. For another example, a whole layer of second bonding layer 507 may also be deposited on the surface of the etched substrate 401. The second bonding layer 507 located on the top surfaces of the first bumps is only remained by etching.

S070: the second bonding layer located at the top surfaces of the plurality of first bumps is bonded to the first bonding layer.

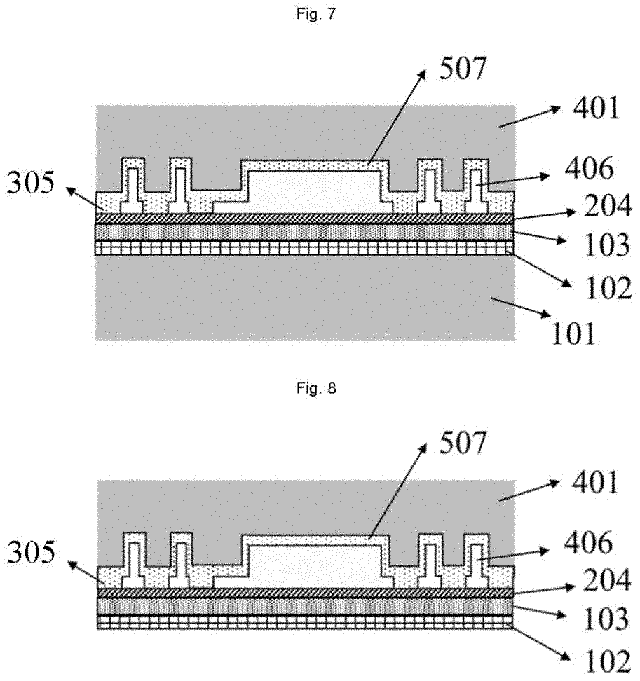

As shown in FIG. 7, a hierarchical structure located on the substrate 401 and a hierarchical structure located on the temporary base substrate 101 are bonded. Specifically, the second bonding layer 507 located at the top surfaces of the plurality of first bumps is bonded to the first bonding layer, so that the hierarchical structure on the temporary base substrate 101 is transferred to the substrate 401.

During bonding, the area of the top surface of the first bump may be controlled by the etched groove 406, so that the area of the second bonding layer 507 located at the top surface of the first bump can be controlled, thereby controlling the bonding area. Through the flexible adjustment of the bonding area, a hierarchical structure on the temporary base substrate 101 and a hierarchical structure on the substrate 401 are prevented from being difficult to apply in mass production due to excessive bonding area, high bonding requirement, and high preparation cost on the basis of meeting the requirements of the bonding reliability. In other words, the present disclosure realizes the balance between the bonding requirement and the bonding reliability by controlling the bonding area.

At S080: the temporary base substrate is removed.

As shown in FIG. 8, after the hierarchical structure located on the temporary base substrate 101 and the hierarchical structure located on the substrate 401 are bonded. The temporary base substrate 101 may be removed by etching, so that the hierarchical structure on the temporary base substrate 101 is transferred to the base 401. At this moment, one side surface, deviating from the substrate 401, of the buffer layer 102 is exposed.

At S090: the buffer layer is etched to form a first groove that exposes the piezoelectric layer.

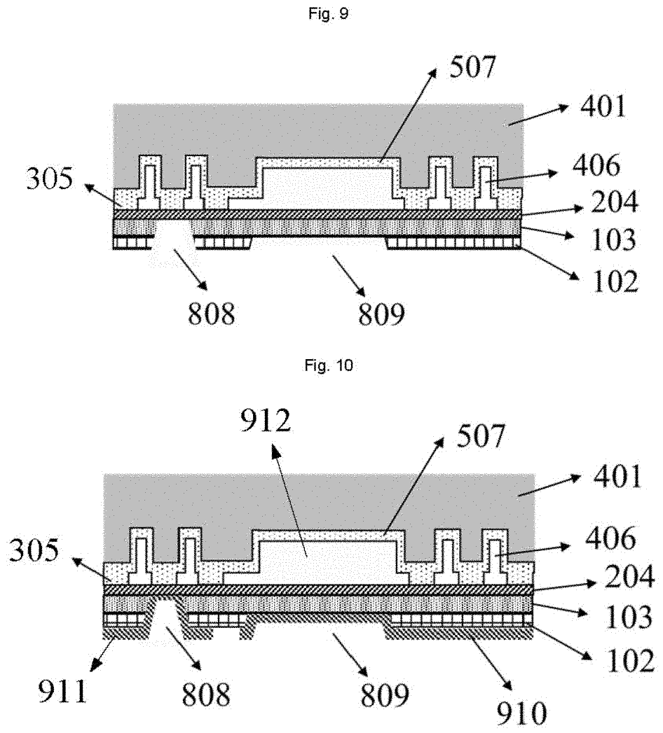

As shown in FIG. 9, a first groove 809 is formed on the buffer layer 102 by etching the buffer layer 102, so that the piezoelectric layer 103 is exposed from the first groove 809.

S100: a second electrode that is in contact with the piezoelectric layer is formed through the first groove.

As shown in FIG. 10, a second electrode 910 is deposited through the first groove 809, so that at least part of the second electrode 910 is in contact with the surface of the exposed piezoelectric layer 103. Therefore, the second electrode 910, the piezoelectric layer 103, and the first electrode 204 form basic functional layers of a resonator.

Optionally, after the first bonding layer is formed on the first electrode 204 through S030, the method further includes that: as shown in FIG. 4, the first bonding layer is patterned to form a plurality of second bumps 305 first. It is to be understood that the plurality of bumps 305 are in one-to-one correspondence with the plurality of first bumps up and down. Then, as shown in FIG. 6 and FIG. 7, when the first bonding layer is bonded to the second bonding layer 507, the second bonding layer 507 located on the top surfaces of the first bumps is aligned and bonded to the top surfaces of the second bumps 305.

Optionally, as shown in FIG. 9 and FIG. 10, after the temporary base substrate 101 is removed, the method further includes that: the buffer layer 102 and the piezoelectric layer 103 are etched sequentially to expose a second groove 808 of the first electrode 204. An extraction electrode 911 is deposited through the second groove 808, so that at least part of the extraction electrode 911 is connected to the exposed first electrode 204. Thus, the first electrode 204 is led to one side, deviating from the substrate 401, of the buffer layer 102, so as to facilitate connecting a line thereto. It is to be understood that there is a certain gap between the extraction electrode 911 and the second electrode 910, so as to ensure the insulation there between.

In some implementation modes, the extraction electrode 911 and the second electrode may be formed at one step. For example, as shown in FIG. 10, a whole layer of conductive layer is deposited on one side surface, deviating from the substrate 401, of the buffer layer 102, that is, the conductive layer covers the surface of the buffer layer 102, the first groove 809, and the second groove 808, and then the conductive layer is disconnected between the first groove 809 and the second groove slot 808 by etching to form two independent parts. One part is formed as the first electrode 204 and the other part is used as the extraction electrode 911.

Optionally, as shown in FIG. 10, a plurality of first bumps include a first sub-bump and a second sub-bump. A third groove 912 corresponding to the position of the first groove 809 is formed between the first sub-bump and the second sub-bump. In other words, the third groove 912 may serve as an air cavity structure of the resonator, so that the orthographic projections of the first electrode 204, the second electrode 910 that is located in the first groove 809 and is in contact with the piezoelectric layer 103, and the third groove 912 on the substrate 401 have an overlapping area. The overlapping area is an effective operating area of the resonator.

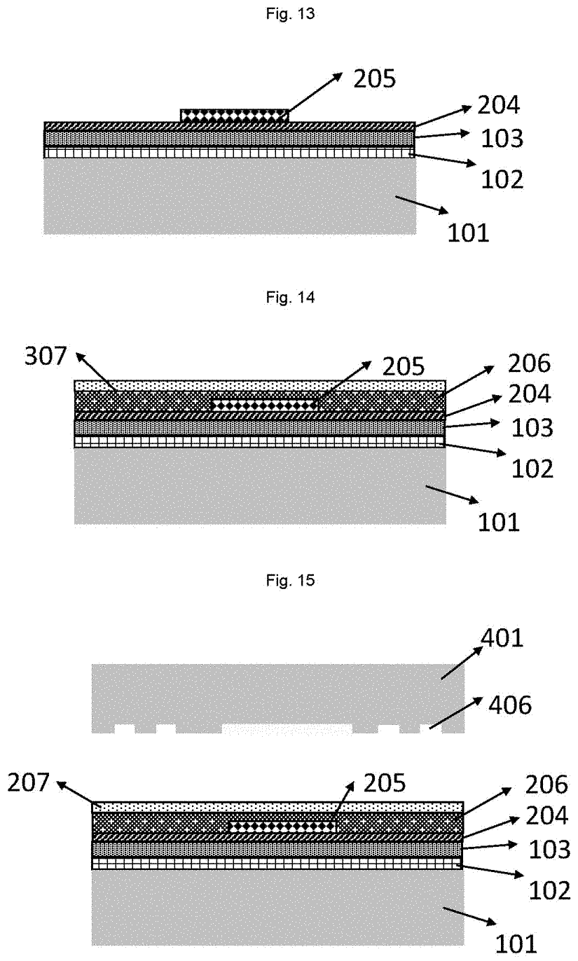

As shown in FIG. 3 and FIG. 13, both the first bonding layer and the second bonding layer 507 are metal layers, such as a gold layer. Since both the first bonding layer and the second bonding layer 507 are metal layers, the parasitic capacitance of the part can be effectively avoided, and the performance of a device can be improved.

As shown in FIG. 13 and FIG. 14, a sacrificial layer 205 is deposited on the first electrode 204, and a support layer 206 and a first bonding layer 307 are deposited on the first electrode 204 and the sacrificial layer 205. The sacrificial layer 205 is made of SiO₂, polycrystalline silicon, or other materials. As an example, when the SiO₂ is used as a sacrificial material, VHF is generally used for removing the sacrificial layer. The support layer is made of a material with low reactivity with VHF, such as SiNx, so as to prevent structural damage caused by the damage of the support layer.

As shown in FIG. 10 and FIG. 15, the compressed height of the first bonding layer 307 and the second bonding layer 507 after being bonded is not greater than the height of the first bump. The bonding pressure applied to the first bonding layer 307 and the second bonding layer 507 is positively related to the area of the top surface of the first bump. First, the height of the first bump is controlled to be not less than the compressed height of the first bonding layer and the second bonding layer during bonding. During bonding, only the second bonding layer on the bumps may be in contact with the first bonding layer, and at this moment, the bonding pressure is positively related to the area of the top surface of the first bump. The bonding pressure can be controlled within an appropriate pressure range by setting the area of the first bump within the appropriate range.

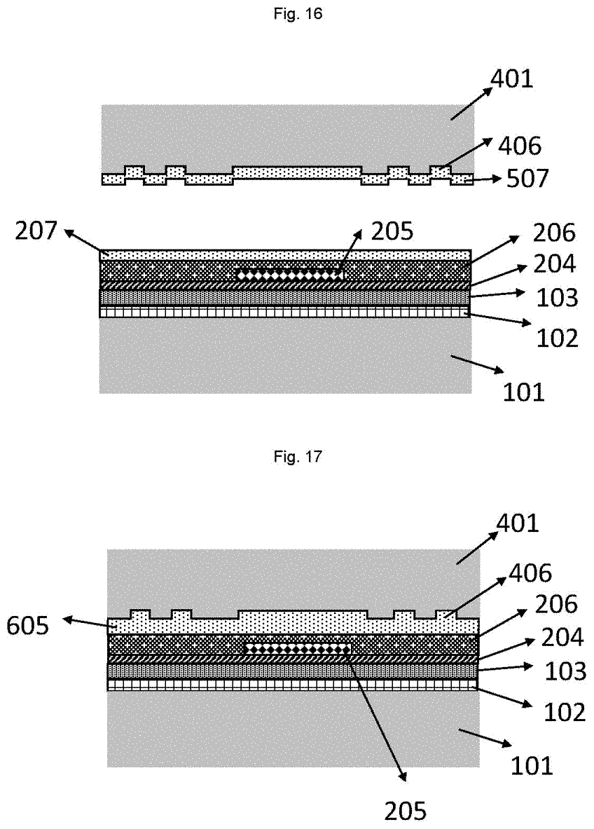

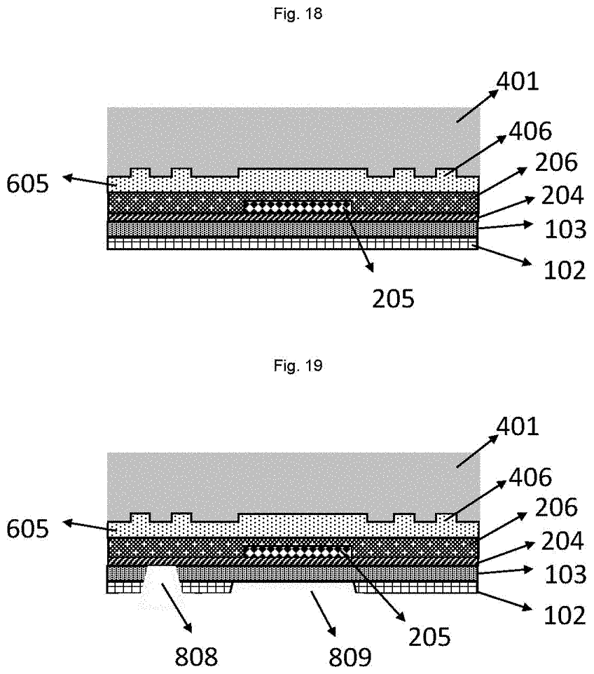

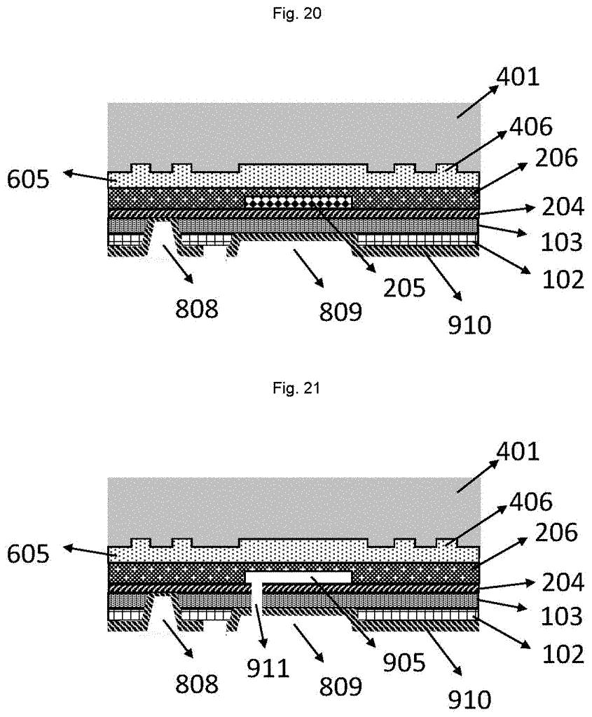

As shown in FIG. 16, FIG. 17, FIG. 18, FIG. 19, FIG. 20, and FIG. 21, a compressed height of the first bonding layer 307 and the second bonding layer 507 after being bonded is equal to a height of the first bump. The second bonding layer 507 located at the top surfaces of the plurality of first bumps is bonded to the first bonding layer 307. Since the height of the first bump is equal to the compressed height of the first bonding layer 307 during bonding, after the bonding is ended, the third groove 912 is just filled with the material of the first bonding layer 307, approximately realizing the overall global bonding effect of the first bonding layer 307 and the second bonding layer 507. Generally, during bonding, the bonding pressure is positively related to the bonding area. The overall global bonding requires that the bonding pressure of a bonding machine is high, and the requirements for the bonding machine are high. By the method of the present disclosure, the abovementioned purpose can be achieved in a case of a low bonding pressure, which enhances the bonding stability and is beneficial to subsequent process, particularly, the etching of the first groove 809 and the second groove 808.

A release hole is formed in the substrate 401, and the sacrificial layer is removed through the release hole to form a cavity.

The substrate 401 is aligned with the temporary base substrate 101, and then is bonded in a vacuum environment at 260° C. to 400° C. By controlling the height of the first bump to be equal to the compressed height during bonding, after the bonding is ended, the third groove 907 is just filled by gold, so as to achieve an overall bonding effect. In this way, since there is cavity structure in the device, a laminated structure below the third groove 907 is directly supported by the filled first bonding layer 307. When the temporary base substrate 101 is etched, the device will not deform due to pressure difference between the third groove 907 and the external environment, which avoids the deterioration of the device performance that may be caused by deformation. In addition, the etched parts of the first groove 809 and the second groove 808 are also be supported by the first bonding layer in the grooves, so a cracking phenomenon during etching can be avoided, thereby improving the quality of etching.

In another aspect of the embodiments of the present disclosure, a single crystal film bulk acoustic resonator 1002 is provided, which includes single crystal film bulk acoustic resonators 1002 prepared by any of the abovementioned manufacturing method for a single crystal film bulk acoustic resonator 1002. Specifically, as shown in FIG. 10, the single crystal film bulk acoustic resonator 1002 includes a substrate 401. The substrate 401 has a plurality of first bumps. A second bonding layer 507 covering top surfaces of a plurality of first bumps is formed on the surface of the substrate 401. A first bonding layer is bonded on the second bonding layer 507. A first electrode 204, a piezoelectric layer 103, and a buffer layer 102 that are stacked are sequentially formed on the first bonding layer. A first groove 809 that exposes the piezoelectric layer 103 is formed in the buffer layer 102. A second electrode 910 that is in contact with the piezoelectric layer 103 is formed on the first groove 809.

During bonding, the area of the top surface of the first bump may be controlled by the etched groove 406, so that the area of the second bonding layer 507 located at the top surface of the first bump can be controlled, thereby controlling the bonding area. Through the flexible adjustment of the bonding area, a hierarchical structure on the temporary base substrate 101 and a hierarchical structure on the substrate 401 are prevented from being difficult to apply in mass production due to excessive bonding area, high bonding requirement, and high preparation cost on the basis of meeting the requirements of the bonding reliability. In other words, the present disclosure realizes the balance between the bonding requirement and the bonding reliability by controlling the bonding area.

Optionally, both the first bonding layer and the second bonding layer 507 are metal layers, for example, gold layers. Since both the first bonding layer and the second bonding layer 507 are metal layers, the parasitic capacitance of the part can be effectively avoided, and the performance of a device can be improved. Of course, the first bonding layer 307 and the second bonding layer 507 may also be made of the same material.

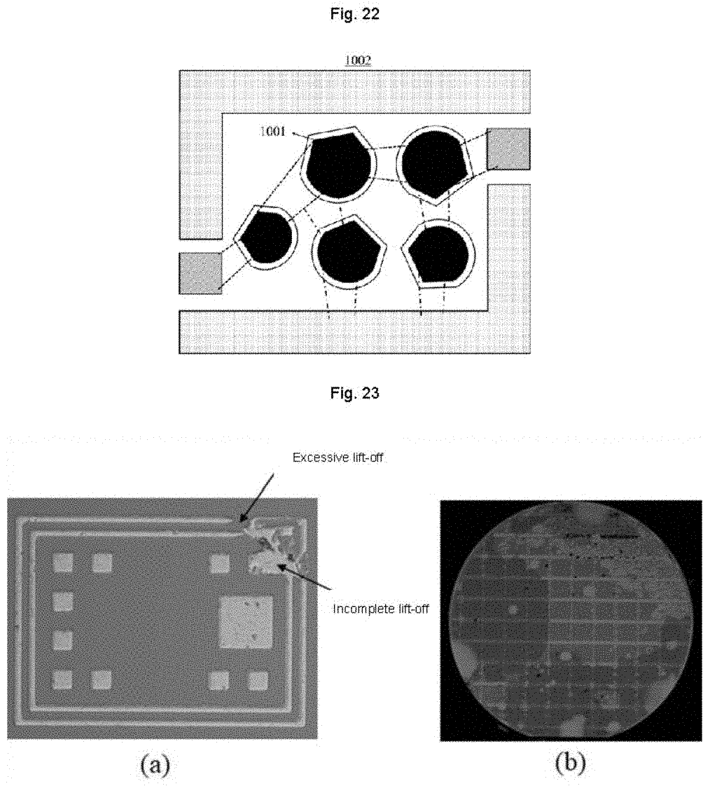

In yet another aspect of the embodiments of the present disclosure, a filter is provided, as shown in FIG. 11 and FIG. 22, which includes a plurality of single crystal film bulk acoustic resonators of any one of the above 1002. The plurality of single crystal film bulk acoustic resonators 1002 share a same substrate 401. The plurality of single crystal film bulk acoustic resonators 1002 are connected in series and/or in parallel. A first annular sealing structure 1003 surrounding the plurality of single crystal film bulk acoustic resonators 1002 is formed on the substrate 401. The first annular sealing structure includes a first sealing ring and a second sealing ring that are stacked on the substrate 401 and are bonded mutually. Thus, a circle of bonding area may be formed on the periphery of the filter to serve as a sealing ring, which can effectively prevent impurities from entering a silicon wafer, and improves the reliability of the process.

In some implementation modes, the first sealing ring and the foregoing second bonding layer 507 may be formed at the same step (a reference conductive layer including an extraction electrode 911 and a second electrode 910). Similarly, the second sealing ring and the foregoing first bonding layer may be formed at the same step (the reference conductive layer including the extraction electrode 911 and the second electrode 910).

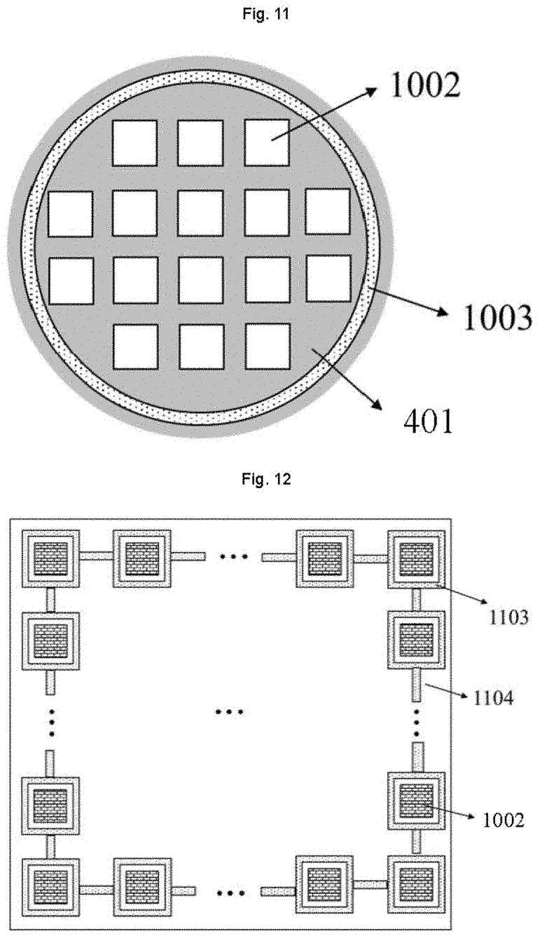

Optionally, as shown in FIG. 12, in order to further improve the sealing effect, a second annular sealing structure 1103 may also be formed on the periphery of each single crystal film bulk acoustic resonator 1002. The second annular sealing structure 1103 includes a third sealing ring and a fourth sealing ring that are stacked on the substrate 401 and are bonded mutually.

In some implementation modes, the first sealing ring and the third sealing ring may be formed at single crystal film bulk acoustic resonator step. Similarly, the second sealing ring and the fourth sealing ring may be formed at single crystal film bulk acoustic resonator step.

Optionally, as shown in FIG. 12, in order to further improve the sealing effect, the filter further includes a sealing wall structure 1104. Two adjacent second annular sealing structures 1103 are connected through the sealing wall structure 1104. The sealing wall structure 1104 includes a fifth sealing ring and a sixth sealing ring that are stacked on the substrate 401 and are bonded mutually.

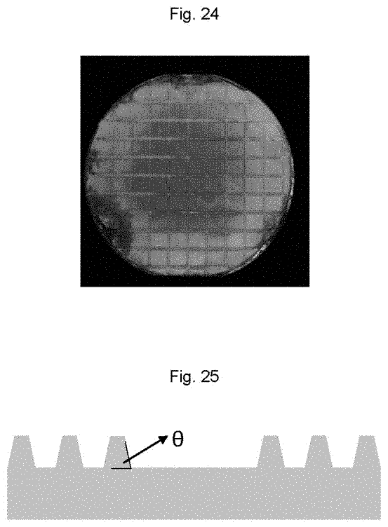

Referring to FIG. 23 and FIG. 24, a common method for controlling the bonding area is to directly pattern the bonding layer. The bonding layer is made of Au. The purpose of controlling the bonding area is achieved by controlling the area of Au. However, Au is generally realized through a Lift-off process. When the bonding area is required to be small, an excessive lift-off or incomplete lift-off phenomenon of Au is easily caused, as shown in FIG. 23(a), which causes a phenomenon of poor bonding, as shown in FIG. 23(b). According to the present disclosure, the area of the first bump is controlled through an etched groove, a small-area Au lift-off process is avoided, and an uniform or flat Au surface can be obtained, so as to improve the bonding quality, as shown in FIG. 24.

As shown in FIG. 25, a side wall of the sealing wall structure 1104 forms an inclination angle. Deep reaction ion etching is adopted, and C4F8 gas and SF6 gas are alternately introduced into the reaction chamber. The C4F8 gas is introduced, so that a polymer film may be formed on a surface of a silicon side wall, thereby achieving a purpose of passivating. The SF6 gas is introduced to perform physical and chemical etching. The C4F8 gas and the SF6 gas are alternately introduced to perform passivating and etching alternately, so that the inclination angle θ of the side wall of a protective wall 111 is controlled. The smaller the inclination angle θ is, the higher the stability of the device. In order to ensure the stability of the device, the inclination angle θ is less than 70°.

In some implementation modes, the first sealing ring and the fifth sealing ring may be formed at the same step. Similarly, the second sealing ring and the sixth sealing ring may be formed at the same step.

The above is only the preferred embodiments of the present disclosure, and is not intended to limit the present disclosure. For those skilled in the art, the present disclosure may have various changes and variations. Any modifications, equivalent replacements, improvements and the like made within the spirit and principle of the present disclosure shall fall within the scope of protection of the present disclosure.

1. A manufacturing method for a single crystal film bulk acoustic resonator, comprising:
providing a temporary base substrate;
sequentially forming a buffer layer, a piezoelectric layer, and a first electrode that are stacked on the temporary base substrate;
forming a first bonding layer on the first electrode;
providing a substrate;
etching the substrate to form a plurality of first bumps on a surface of the substrate;
forming, on the surface of the substrate, a second bonding layer covering top surfaces of the plurality of first bumps;
bonding the second bonding layer located at the top surfaces of the plurality of first bumps to the first bonding layer;
removing the temporary base substrate;
etching the buffer layer to form a first groove that exposes the piezoelectric layer; and
forming a second electrode that is in contact with the piezoelectric layer through the first groove.

2. The manufacturing method for a single crystal film bulk acoustic resonator of claim 1, after forming the first bonding layer on the first electrode, further comprising:
patterning the first bonding layer to form a plurality of second bumps for bonding with the second bonding layer located at the top surfaces of the first bumps.

3. The manufacturing method for a single crystal film bulk acoustic resonator of claim 1, after removing the temporary base substrate, further comprising:
sequentially etching the buffer layer and the piezoelectric layer to form a second groove that exposes the first electrode; and
forming an extraction electrode connected to the first electrode through the second groove.

4. The manufacturing method for a single crystal film bulk acoustic resonator of claim 1, wherein the plurality of first bumps comprise a first sub-bump and a second sub-bump; and a third groove corresponding to a position of the first groove is formed between the first sub-bump and the second sub-bump.

5. The manufacturing method for a single crystal film bulk acoustic resonator of claim 1, wherein both the first bonding layer and the second bonding layer are metal layers.

6. The manufacturing method for a single crystal film bulk acoustic resonator of claim 4, wherein both the first bonding layer and the second bonding layer are metal layers.

7. The manufacturing method for a single crystal film bulk acoustic resonator of claim 6, wherein a sacrificial layer is deposited on the first electrode, and a support layer and the first bonding layer are deposited on the first electrode and the sacrificial layer.

8. The manufacturing method for a single crystal film bulk acoustic resonator of claim 7, wherein a compressed height of the first bonding layer and the second bonding layer after being bonded is not greater than a height of the first bump.

9. The manufacturing method for a single crystal film bulk acoustic resonator of claim 8, wherein the compressed height of the first bonding layer and the second bonding layer after being bonded is equal to the height of the first bump.

10. The manufacturing method for a single crystal film bulk acoustic resonator of claim 9, wherein bonding pressure applied to the first bonding layer and the second bonding layer is positively related to an area of the top surface of the first bump.

11. The manufacturing method for a single crystal film bulk acoustic resonator of claim 7, wherein a release hole is formed in the substrate; and the sacrificial layer is removed through the release hole to form a cavity.

12. A single crystal film bulk acoustic resonator, comprising a substrate, wherein a surface of the substrate has a plurality of first bumps; a second bonding layer covering top surfaces of a plurality of the first bumps is formed on the surface of the substrate; a first bonding layer is bonded on the second bonding layer; a first electrode, a piezoelectric layer, and a buffer layer that are stacked are sequentially formed on the first bonding layer; a first groove that exposes the piezoelectric layer is formed in the buffer layer; and a second electrode that is in contact with the piezoelectric layer is formed on the first groove.

13. The single crystal film bulk acoustic resonator of claim 12, wherein both the first bonding layer and the second bonding layer are metal layers.

14. The single crystal film bulk acoustic resonator of claim 13, wherein the first bonding layer and the second bonding layer are of same materials.

15. A filter, comprising a plurality of single crystal film bulk acoustic resonators of claim 12, wherein the plurality of single crystal film bulk acoustic resonators share a same substrate, and the plurality of single crystal film bulk acoustic resonators are connected in series or in parallel; a first annular sealing structure surrounding the plurality of single crystal film bulk acoustic resonators is formed on the substrate; and the first annular sealing structure comprises a first sealing ring and a second sealing ring that are stacked on the substrate and are bonded mutually.

16. The filter of claim 15, wherein a second annular sealing structure is also formed on the periphery of the single crystal film bulk acoustic resonators; and the second annular sealing structure comprises a third sealing ring and a fourth sealing ring that are stacked on the substrate and are bonded mutually.

17. The filter of claim 16, further comprising a sealing wall structure, wherein two adjacent second annular sealing structures are connected through the sealing wall structure.

18. The filter of claim 17, wherein the sealing wall structure comprises a fifth sealing ring and a sixth sealing ring that are stacked on the substrate and are bonded mutually.

19. The filter of claim 18, wherein a side wall of the sealing wall structure forms an inclination angle.

20. The filter of claim 19, wherein the angle of the inclination angle is less than 70°.
